(19) United States
(12) Patent Application Publication
(10) Pub. No.: US 2026/0020447 A1
(43) Pub. Date: Jan. 15, 2026

(54) DISPLAY PANEL AND MANUFACTURING METHOD THEREOF, AND DISPLAY APPARATUS

(71) Applicant: Wuhan Tianma Microelectronics Co., Ltd., Wuhan (CN)

(72) Inventors: Shuangli ZHU, Wuhan (CN); Qiyong KE, Wuhan (CN)

(73) Assignee: Wuhan Tianma Microelectronics Co., Ltd., Wuhan, HB (CN)

(21) Appl. No.: 19/335,298

(22) Filed: Sep. 22, 2025

(30) Foreign Application Priority Data
Apr. 29, 2025 (CN) 202510558801.8

(51) Int. Cl. H10K 59/122; H10K 59/12

(52) U.S. Cl. CPC H10K 59/122; H10K 59/1201

(57) ABSTRACT

The embodiments of the present disclosure provide a display panel and a manufacturing method thereof, and a display apparatus, related to the field of display technologies, for reducing the reflectivity of the display panel, mitigating the light leakage issue between adjacent sub-pixels, and improving the display effect of the display panel. The display panel includes a first pixel definition layer including a first pixel opening, a second pixel definition layer including a second pixel opening, and a partition portion including a recessed portion and/or a first protruding portion, at least one of the first pixel definition layer and the second pixel definition layer includes a light-shielding material. The second pixel opening at least partially overlaps the first pixel opening along a direction perpendicular to the plane of the substrate. The partition portion at least partially surrounds the first pixel opening and the second pixel opening.

### CROSS-REFERENCE TO RELATED APPLICATION

The present application claims priority to Chinese Patent Application No. 202510558801.8, filed on Apr. 29, 2025, the content of which is incorporated herein by reference in its entirety.

### TECHNICAL FIELD

The present disclosure relates to the field of display technologies and, in particular, to a display panel and a manufacturing method thereof, and a display apparatus.

### BACKGROUND

Organic Light-Emitting Diodes (OLEDs) have the advantages of self-luminescence, no need for a backlight, wide color gamut, high contrast, small thickness, wide viewing angle, and fast response speed. As current-driven light-emitting devices, OLED display panels have been increasingly used in high-performance displays.

Currently, the performance of OLED display panels still needs to be improved.

### SUMMARY

In view of the above, embodiments of the present disclosure provide a display panel and a manufacturing method thereof, and a display apparatus, which are used to reduce the reflectivity of the display panel, mitigate the light leakage issue, and improve the display effect.

In a first aspect, an embodiment of the present disclosure provides a display panel, including: a substrate; a first pixel definition layer located on a side of the substrate, where the first pixel definition layer includes a first pixel opening; a second pixel definition layer located on a side of the first pixel definition layer away from the substrate, where at least one of the first pixel definition layer and the second pixel definition layer includes a light-shielding material, the second pixel definition layer includes a second pixel opening, and the second pixel opening at least partially overlaps the first pixel opening along a direction perpendicular to a plane of the substrate; a light-emitting layer at least partially located in the first pixel opening and the second pixel opening; and a partition portion at least partially surrounding the first pixel opening and the second pixel opening, where the partition portion includes a recessed portion and/or a first protrusion portion, the recessed portion is recessed from a surface of the second pixel definition layer away from the first pixel definition layer toward a direction close to the first pixel definition layer, and the first protrusion portion protrudes from the surface of the second pixel definition layer away from the first pixel definition layer toward a direction away from the first pixel definition layer.

In a second aspect, an embodiment of the present disclosure provides a method for manufacturing a display panel, including: providing a substrate; forming a first pixel definition layer on a side of the substrate, where the first pixel definition layer includes a first pixel opening; forming a second pixel definition layer on a side of the first pixel definition layer away from the substrate, where at least one of the first pixel definition layer and the second pixel definition layer includes a light-shielding material, the second pixel definition layer includes a second pixel opening, and the second pixel opening at least partially overlaps the first pixel opening along a direction perpendicular to a plane of the substrate; and forming a partition portion at least partially surrounding the first pixel opening and the second pixel opening, where the partition portion includes a recessed portion and/or a first protrusion portion, the recessed portion is recessed from a surface of the second pixel definition layer away from the first pixel definition layer toward a direction close to the first pixel definition layer, and the first protrusion portion protrudes from the surface of the second pixel definition layer away from the first pixel definition layer toward a direction away from the first pixel definition layer.

In a third aspect, an embodiment of the present disclosure provides a display apparatus, including the above display panel.

In the display panel and the manufacturing method thereof and the display apparatus according to the embodiments of the present disclosure, the first pixel definition layer and the second pixel definition layer are provided in the display panel, and at least one of the first pixel definition layer and the second pixel definition layer includes the light-shielding material that can absorb external ambient light and ambient light reflected by the metal structure inside the display panel, so that the reflectivity of the display panel can be reduced.

In addition, in the embodiments of the present disclosure, by providing the partition portion in the display panel, the leakage current path can be extended or blocked, thereby mitigating the light leakage issue, and improving the display effect of the display panel.

### BRIEF DESCRIPTION OF DRAWINGS

To clearly illustrate the technical solutions of the embodiments of the present disclosure, the drawings required in the embodiments are briefly introduced below. It is appreciated that the drawings described below are only some embodiments of the present disclosure. For those skilled in the art, other drawings can be obtained according to these drawings.

FIG. 1 is a schematic top view of a display panel according to some embodiments of the present disclosure;

FIG. 2 is a schematic cross-sectional view of a display panel according to some embodiments of the present disclosure;

FIG. 3 is a schematic cross-sectional view of another display panel according to some embodiments of the present disclosure;

FIG. 4 is a schematic cross-sectional view of another display panel according to some embodiments of the present disclosure;

FIG. 5 is a schematic cross-sectional view of another display panel according to some embodiments of the present disclosure;

FIG. 6 is a schematic cross-sectional view of another display panel according to some embodiments of the present disclosure;

FIG. 7 is a schematic cross-sectional view of another display panel according to some embodiments of the present disclosure;

FIG. 8 is a schematic cross-sectional view of another display panel according to some embodiments of the present disclosure;

FIG. 9 is a schematic flowchart of a method for manufacturing a display panel according to some embodiments of the present disclosure;

FIG. 10 is a schematic flowchart of another method for manufacturing a display panel according to some embodiments of the present disclosure;

FIG. 11 is a schematic flowchart of another method for manufacturing a display panel according to some embodiments of the present disclosure;

FIG. 12 is a schematic flowchart of another method for manufacturing a display panel according to some embodiments of the present disclosure;

FIG. 13 is a schematic flowchart of another method for manufacturing a display panel according to some embodiments of the present disclosure;

FIG. 14 is a schematic flowchart of a further method for manufacturing a display panel according to some embodiments of the present disclosure;

FIG. 15 is a schematic flowchart of another method for manufacturing a display panel according to some embodiments of the present disclosure;

FIG. 16 is a schematic flowchart of another method for manufacturing a display panel according to some embodiments of the present disclosure;

FIG. 17 is a schematic flowchart of another method for manufacturing a display panel according to some embodiments of the present disclosure; and

FIG. 18 is a schematic diagram of a display apparatus according to some embodiments of the present disclosure.

### DESCRIPTION OF EMBODIMENTS

To better understand the technical solutions of the present disclosure, embodiments of the present disclosure are described in detail below in conjunction with the drawings.

It should be clarified that the described embodiments are only some, rather than all, of embodiments of the present disclosure. According to embodiments of the present disclosure, all other embodiments obtained by those skilled in the art shall fall within the protection scope of the present disclosure.

The terms used in the embodiments of the present disclosure are only for the purpose of describing specific embodiments and are not intended to limit the present disclosure. The singular forms “a/an”, “said” and “the” used in the embodiments of the present disclosure and the claims are intended to include plural forms unless the context clearly indicates otherwise.

It should be understood that the term “and/or” herein is only used to describe the associated relationship of associated objects, indicating that three relationships may exist. For example, A and/or B can represent: A exists alone, A and B exist at the same time, and B exists alone. In addition, the character “/” herein generally indicates that the associated objects are in an “or” relationship.

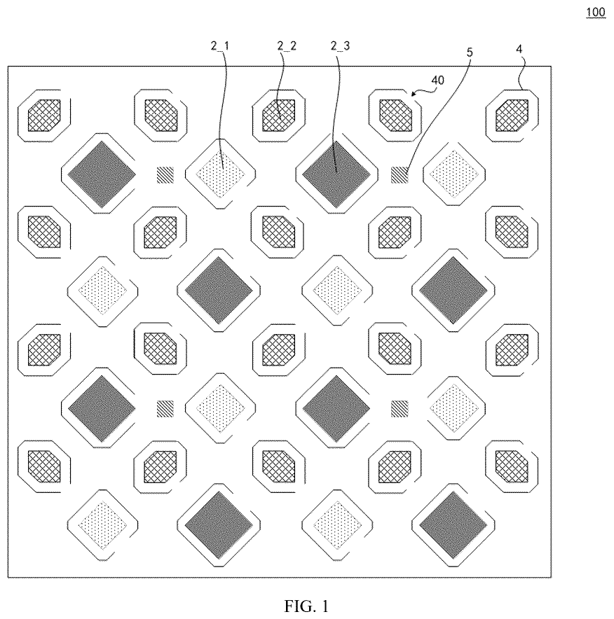

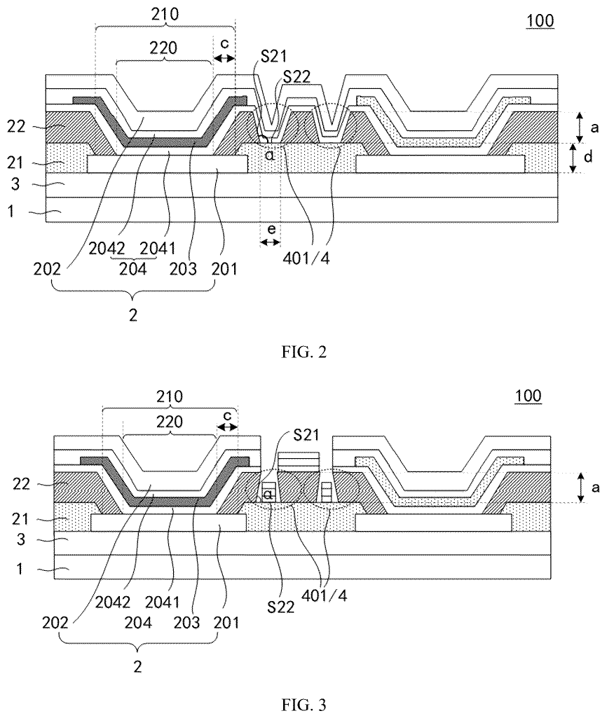

An embodiment of the present disclosure provides a display panel. As shown in FIG. 1 and FIG. 2, where FIG. 1 is a schematic top view of a display panel according to some embodiments of the present disclosure, and FIG. 2 is a schematic cross-sectional view of a display panel according to some embodiments of the present disclosure, a display panel 100 includes a substrate 1 and a plurality of sub-pixels 2 formed on a side of the substrate 1. In some embodiments of the present disclosure, the display panel 100 includes sub-pixels 2 of multiple colors. FIG. 1 schematically shows that the sub-pixels 2 include a first sub-pixel 2_1, a second sub-pixel 2_2 and a third sub-pixel 2_3.

As shown in FIG. 2, the sub-pixels 2 include a light-emitting element. In some embodiments of the present disclosure, the light-emitting element includes any one of an organic light-emitting diode (OLED), a micro light-emitting diode (Micro LED), or a quantum light-emitting diode (QLED).

As shown in FIG. 2, the light-emitting element includes a first electrode 201, a light-emitting layer 203, a second electrode 202, and a common layer 204. The common layer 204 can enhance the migration and recombination efficiency of carriers.

In some embodiments of the present disclosure, as shown in FIG. 2, the common layer 204 includes a first common sub-layer 2041 and a second common sub-layer 2042. The first common sub-layer 2041 is located between the first electrode 201 and the light-emitting layer 203, and the second common sub-layer 2042 is located between the second electrode 202 and the light-emitting layer 203.

In some embodiments of the present disclosure, the first electrodes 201 of different sub-pixels 2 are independent of each other, and the second electrodes 202 of multiple sub-pixels 2 are electrically connected to each other.

In some embodiments of the present disclosure, the first electrode 201 includes an anode, and the second electrode 202 includes a cathode. The first common sub-layer 2041 includes one or more of a hole injection layer (HIL), a hole transport layer (HTL), and a hole block layer (HBL). The second common sub-layer 2042 includes one or more of an electron injection layer (EIL), an electron transport layer (ETL), and an electron block layer (EBL).

As shown in FIG. 2, the display panel 100 further includes a first pixel definition layer 21 and a second pixel definition layer 22. The first pixel definition layer 21 is located on a side of the substrate 1, and the first pixel definition layer 21 includes a first pixel opening 210. The second pixel definition layer 22 is located on a side of the first pixel definition layer 21 away from the substrate 1, and the second pixel definition layer 22 includes a second pixel opening 220. Along a direction perpendicular to a plane of the substrate 1, the second pixel opening 220 at least partially overlaps the first pixel opening 210. The light-emitting layer 203 is at least partially located in the first pixel opening 210 and the second pixel opening 220. The second pixel opening 220 and the first pixel opening 210 define the light-emitting area of the sub-pixel 2.

As shown in FIG. 2, the display panel 100 includes a driving function layer 3 located on a side of the substrate 1, and the driving function layer 3 includes a pixel driving circuit for driving the light-emitting element to emit light. For example, the driving function layer includes a semiconductor layer, a metal layer and an insulating layer arranged in a stacked manner, and the metal layer includes a metal structure such as an electrode and a trace. The trace includes a scanning line and a data line electrically connected to the pixel driving circuit. The metal structure and the first electrode 201 of the light-emitting element may both reflect the ambient light incident on their surfaces, and the reflected light emitted from the display panel may affect the contrast of the display panel.

In some embodiments of the present disclosure, at least one of the first pixel definition layer 21 and the second pixel definition layer 22 includes a light-shielding material. The light-shielding material can absorb external ambient light and ambient light reflected by the reflective structure inside the display panel, which is beneficial to reducing the reflectivity of the display panel and improving the contrast of the display panel.

During the manufacturing of the display panel 100, the light-emitting layer 203 can be manufactured using a fine metal mask, and the light-emitting layers 203 of different sub-pixels 2 are arranged at intervals. In some embodiments of the present disclosure, a common mask can be used to manufacture the common layer 204. Therefore, the common layer 204 is arranged in communication between two adjacent sub-pixels 2. That is, the common layer 204 is generally an entire surface structure covering all sub-pixels 2 in the display panel 100. In the related art, when a certain sub-pixel 2 emits light, in addition to the normal process of longitudinal migration of carriers from a respective cathode and/or anode to the corresponding light-emitting layer 203, there may also be lateral migration of carriers between different sub-pixels 2 through the common layer 204. The lateral flow of carriers between two adjacent sub-pixels generates lateral leakage current, which leads to the problem of mutual crosstalk between different sub-pixels when the display panel displays images. For example, when the turn-on voltages of two adjacent sub-pixels 2 are close, the lateral leakage current may cause the sub-pixel 2 that do not need to be lit to suffer from the light leakage issue.

In some embodiments of the present disclosure, as shown in FIG. 1 and FIG. 2, the display panel 100 further includes a partition portion 4, and the partition portion 4 at least partially surrounds the first pixel opening 210 and the second pixel opening 220.

As shown in FIG. 2, along the direction perpendicular to the plane of the substrate 1, the partition portion 4 is located on a side of the common layer 204 close to the substrate 1. The partition portion 4 can increase the length of the common layer 204 located between two adjacent sub-pixels 2, or partition the common layer 204 between two adjacent sub-pixels 2. Therefore, the partition portion 4 can suppress the lateral leakage current caused by the flow of carriers between two adjacent sub-pixels 2, thereby avoiding the light leakage of the light-emitting element, and improving the display effect.

It can be understood that the above term “at least partially surround” includes “partially surround” and “surround”. The term “partially surround” refers to “open surround”. For example, as shown in FIG. 1, the partition portion 4 includes a notch 40, that is, the partition portion 4 surrounds one sub-pixel 2 in an open manner. The term “surround” refers to “closed surround”. In other words, the partition portion 4 is a closed ring structure, and the surrounded sub-pixel 2 is located in the ring structure formed by the partition portion 4.

In some embodiments of the present disclosure, the partition portion 4 can be implemented in various ways, which will be described below.

As shown in FIG. 2 and FIG. 3, where FIG. 3 is a schematic cross-sectional view of another display panel according to some embodiments of the present disclosure, in some embodiments of the present disclosure, the partition portion 4 can be configured to include a recessed portion 401 recessed toward a side of the substrate 1. For example, as shown in FIG. 2 and FIG. 3, the recessed portion 401 may be recessed from the surface of the second pixel definition layer 22 away from the first pixel definition layer 21 toward the side close to the first pixel definition layer 21.

As shown in FIG. 2 and FIG. 3, the recessed portion 401 includes a second side surface S21 and a second bottom surface S22 1 close to the substrate 1.

In some embodiments of the present disclosure, as shown in FIG. 2, the angle α between the second side surface S21 and the second bottom surface S22 may be an obtuse angle. Based on this setting method, the common layer 204, formed after the recessed portion 401 is formed, is formed on the second side surface S21 of the recessed portion 401. Compared with the arrangement where the recessed portion 401 as a planar structure, the arrangement of the recessed portion 401 can extend the lateral leakage current path transmitted between two adjacent sub-pixels 2 through the common layer 204, thereby suppressing the transmission of the lateral leakage current and improving the display effect of the display panel.

For example, 90°≤α≤135°. Based on this setting method, while taking into account the manufacturing process yield of the recessed portion 401, a common layer 204 with a larger coverage area can also be formed on the second side surface S21 of the recessed portion 401, which is beneficial to further extending the lateral leakage current path and improving the display effect of the display panel 100.

In some embodiments of the present disclosure, as shown in FIG. 3, the angle α between the second side surface S21 and the second bottom surface S22 may also be an acute angle. Based on this setting method, the common layer 204, formed after the recessed portion 401 is formed, cannot be formed on the second side surface S21 of the recessed portion 401, so that the common layer 204 is disconnected at the recessed portion 401, and the lateral leakage current path transmitted between two adjacent sub-pixels 2 through the common layer 204 is blocked, thereby suppressing the transmission of the lateral leakage current and improving the display effect of the display panel.

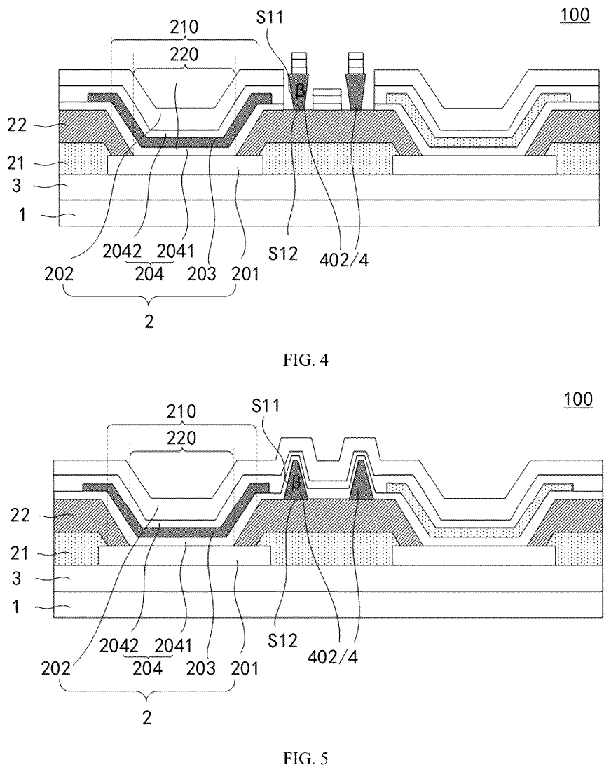

Alternatively, as shown in FIG. 4 and FIG. 5, where FIG. 4 and FIG. 5 are schematic cross-sectional views of another two display panels according to some embodiments of the present disclosure, the partition portion 4 includes a first protrusion portion 402 protruding toward a side away from the substrate 1. For example, as shown in FIG. 4 and FIG. 5, in some embodiments of the present disclosure, the first protrusion portion 402 can protrude from the surface of the second pixel definition layer 22 away from the first pixel definition layer 21 toward the side away from the first pixel definition layer 21.

In some embodiments of the present disclosure, as shown in FIG. 4 and FIG. 5, the first protrusion portion 402 includes a first side surface S11 and a first bottom surface S12 close to the substrate 1.

As shown in FIG. 4, in some embodiments of the present disclosure, the angle β between the first side surface S11 and the first bottom surface S12 and toward the inside of the first protrusion portion 402 may be an obtuse angle. Namely, an area of the first protrusion portion 402 on a side away from the substrate 1 is greater than an area on a side close to the substrate 1. That is, the cross-sectional shape of the first protrusion portion 402 along the plane perpendicular to the substrate 1 is set as an inverted trapezoid. Based on this setting method, the common layer 204, formed after the first protrusion portion 402 is formed, cannot be formed on the first side surface S11, so that the common layer is disconnected at the first protrusion portion 402, and the lateral leakage current path transmitted between two adjacent sub-pixels 2 through the common layer 204 is blocked, thereby suppressing the transmission of the lateral leakage current and improving the display effect of the display panel.

Alternatively, as shown in FIG. 5, in some embodiments of the present disclosure, the angle β between the first side surface S11 and the first bottom surface S12 and toward the inside of the first protrusion portion 402 may be an acute angle. Namely, an area of the first protrusion 402 on a side away from the substrate 1 is smaller than an area on a side close to the substrate 1. That is, the cross-sectional shape of the first protrusion portion 402 along the plane perpendicular to the substrate 1 is set as an upright trapezoid. Based on this setting method, the common layer 204, formed after the first protrusion portion 402 is formed, is formed on the first side surface S11. Compared with the arrangement where the first protrusion portion 402 is provided and the surface of the second pixel definition layer 22 at the position of the first protrusion portion 402 is set as a plane, providing the first protrusion portion 402 can extend the lateral leakage current path transmitted between two adjacent sub-pixels 2 through the common layer 204, thereby suppressing the transmission of the lateral leakage current and improving the display effect of the display panel.

It can be seen from the above that in the display panel 100 according to some embodiments of the present disclosure, by providing the first pixel definition layer 21 and the second pixel definition layer 22 in the display panel 100, and configuring at least one of these layers to include the light-shielding material that can absorb external ambient light and ambient light reflected by the metal structure inside the display panel, the reflectivity of the display panel 100 can be reduced.

Furthermore, in some embodiments of the present disclosure, by providing the partition portion 4 in the display panel 100 that can extend or block the lateral leakage current path between two adjacent sub-pixels 2, the light leakage issue can be reduced and the display effect of the display panel can be improved.

It should be noted that the arrangement of the sub-pixels 2 in FIG. 1 is only for illustration. Those skilled in the art can set the pixel arrangement of the sub-pixels 2 according to different display requirements, which is not limited thereto in the present disclosure.

For example, as shown in FIG. 2 and FIG. 3, in some embodiments of the present disclosure, the recessed portion 401 can be provided in the second pixel definition layer 22, and the recessed portion 401 can penetrate through the second pixel definition layer 22 in the direction perpendicular to the plane of the substrate 1. That is, in some embodiments of the present disclosure, a depth of the recessed portion 401 can be equal to a thickness of the second pixel definition layer 22. Based on this setting method, the depth of the recessed portion 401 can be increased, so that more of the common layer 204 can be accommodated in the recessed portion 401, and the length of the portion of the common layer 204 between two adjacent sub-pixels 2 can be further increased, which is beneficial to solving the light leakage issue of the sub-pixels 2 and improving the display effect.

Furthermore, based on the dual-layer structure of the first pixel definition layer 21 and the second pixel definition layer 22, and when the recessed portion 401 penetrates through the second pixel definition layer 22, regardless of whether the recessed portion 401 overlaps the first electrode 201 in the direction perpendicular to the plane of the substrate 1, the first pixel definition layer 21 can separate the recessed portion 401 and the first electrode 201, which can prevent the patterning process of forming the recessed portion 401, such as an exposure process, from affecting the first electrode 201, and is beneficial to improving the structural reliability of the first electrode 201.

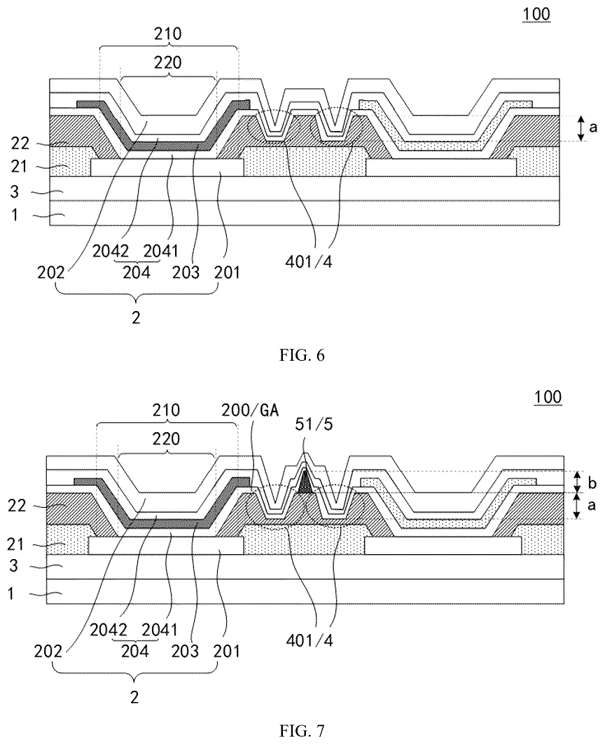

In some embodiments of the present disclosure, as shown in FIG. 6, which is a schematic cross-sectional view of another display panel according to some embodiments of the present disclosure, the partition portion 4 includes the recessed portion 401, and a depth of the recessed portion 401 is smaller than a thickness of the second pixel definition layer 22 in the direction perpendicular to the plane of the substrate 1. That is, the recessed portion 401 does not penetrate through the second pixel definition layer 22.

By adopting this setting method, when selecting the patterning process such as photoresist coating, exposure, developing, and etching to manufacture the second pixel definition layer 22 with the second pixel opening 220 and the recessed portion, in the etching step, it is possible to avoid the contact between the etchant and the first pixel definition layer 21, and to prevent the first pixel definition layer 21 from being affected by the etchant, which is beneficial to protecting the reliability of the first pixel definition layer 21. For example, when the first pixel definition layer 21 includes the light-shielding material, it is possible to avoid the problem that the first pixel definition layer 21 is affected by the etchant and fades, thereby affecting the light-shielding performance and thus causing an increase in the reflectivity of the display panel.

In some embodiments of the present disclosure, as shown in FIG. 1 and FIG. 7, where FIG. 7 is a schematic cross-sectional view of another display panel according to some embodiments of the present disclosure, the display panel 100 further includes a supporting portion 5, which can improve the compressive strength of the display panel 100 and is configured to support the mask used in the manufacturing process to prevent the mask from scratching other previously manufactured film layers.

As shown in FIG. 7, the display panel 100 includes a non-light-emitting area located between two adjacent sub-pixels. The non-light-emitting area includes a spacing area GA arranged staggerly (i.e., in a staggered manner) from the supporting portion 5. The second pixel definition layer 22 includes a spacing portion 200 at least partially located in the spacing area GA. In other words, the spacing portion 200 is a portion of the second pixel definition layer 22 that is arranged to avoid the second pixel opening 220 and the supporting portion 5. That is, the spacing portion 200 and the supporting portion 5 are arranged staggerly in the direction perpendicular to the plane of the substrate 1. As shown in FIG. 7, a distance between a surface of the supporting portion 5 away from the substrate 1 and the substrate 1 is greater than a distance between a surface of the spacing portion 200 away from the substrate 1 and the substrate 1. Based on this setting method, the distance between the supporting portion 5 and the second pixel definition layer 22 can be increased, which is beneficial to using the supporting portion 5 to support the mask used in the manufacturing process of the light-emitting layer.

For example, as shown in FIG. 7, the display panel 100 includes a second protrusion portion 51 that protrudes from the surface of the second pixel definition layer 22 away from the first pixel definition layer 21 toward the side away from the first pixel definition layer 21. The supporting portion 5 includes the second protrusion portion 51.

In some embodiments of the present disclosure, the supporting portion 5 and the second pixel definition layer 22 can be formed in a same process to simplify the manufacturing process of the display panel and improve the process efficiency. In this case, the materials of the supporting portion 5 and the second pixel definition layer 22 are the same, and there is no interface between them.

Alternatively, the supporting portion 5 and the second pixel definition layer 22 can also be formed in different processes. For example, the second pixel definition layer 22 having the second pixel opening 220 can be formed first, and then the supporting portion 5 is manufactured.

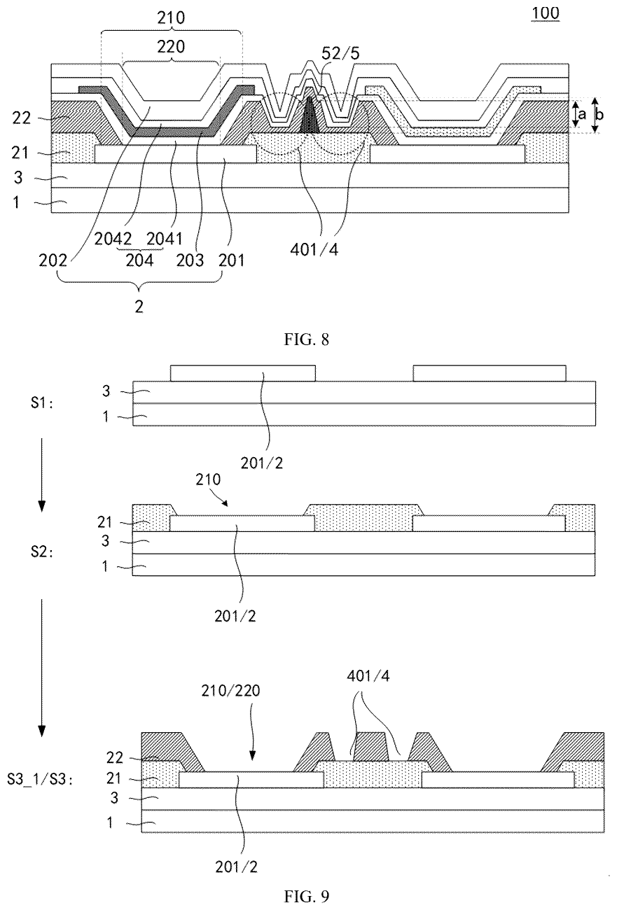

For example, as shown in FIG. 8, which is a schematic cross-sectional view of another display panel according to some embodiments of the present disclosure, the display panel 100 includes a third protrusion portion 52 that protrudes from the surface of the first pixel definition layer 21 away from the substrate 1 toward the side away from the substrate 1. The third protrusion portion 52 is located between the first pixel definition layer 21 and the second pixel definition layer 22 along the direction perpendicular to the plane of the substrate 1. The supporting portion 5 includes the third protrusion portion 52.

It should be understood that the fact that the recessed portion 401 penetrates through the second pixel definition layer 22 as shown in FIG. 8 is only for illustration. In some embodiments of the present disclosure, when the supporting portion 5 includes the third protrusion portion 52, the depth of the recessed portion 401 is less than the thickness of the second pixel definition layer 22. That is, the recessed portion 401 does not penetrate through the second pixel definition layer 22.

In some embodiments of the present disclosure, the supporting portion 5 and the first pixel definition layer 21 are formed in the same process, which can simplify the preparation process of the display panel and improve the process efficiency. In this case, the supporting portion 5 and the first pixel definition layer 21 are made of the same material, and there is no interface between the two.

Alternatively, the supporting portion 5 and the first pixel definition layer 21 can also be formed in different processes. For example, the first pixel definition layer 21 having the first pixel opening 210 can be formed first, and then the supporting portion 5 is manufactured.

For example, as shown in FIG. 7 and FIG. 8, a height b of the supporting portion 5 satisfies: b≥1 μm. The height of the supporting portion 5 refers to the distance between the surface of the supporting portion 5 away from the substrate 1 and the surface of the supporting portion 5 close to the substrate 1. Based on this setting method, the supporting effect of the supporting portion 5 can be ensured, and when the supporting portion 5 is used to support the mask, the distance between the mask and the previously formed film layer can be increased, thereby preventing the mask from affecting the previous film layer.

For example, as shown in FIG. 2, FIG. 3, FIG. 6, FIG. 7 and FIG. 8, the partition portion 4 includes the recessed portion 401, and a depth a of the recessed portion 401 satisfies: a≥0.6 μm, so as to ensure that the common layer 204 accommodated in the recessed portion 401 has a sufficient length to ensure that the lateral leakage current path between two adjacent sub-pixels 2 is extended.

In some embodiments of the present disclosure, as shown in FIG. 2, a minimum distance c between an edge of the first pixel opening 210 and an edge of the second pixel opening 220 satisfies: c≥1.5 μm. For example, FIG. 2 schematically shows that an area of the first pixel opening 210 is larger than an area of the second pixel opening 220, and the second pixel opening 220 is completely located in the first pixel opening 210. Based on this setting method, the difficulty of aligning the first pixel opening 210 and the second pixel opening 220 during the manufacturing process can be reduced, which is beneficial to improving the alignment accuracy of the two openings.

For example, as shown in FIG. 2, a thickness d of the first pixel definition layer 21 satisfies: d≥1 μm. When the first pixel definition layer 21 is configured to include the light-shielding material, the light-shielding performance of the first pixel definition layer 21 can be improved.

In some embodiments of the present disclosure, as shown in FIG. 2, the partition portion 4 includes the recessed portion 401, and a width e of the recessed portion 401 satisfies: e≥2 μm. A width direction of the recessed portion 401 is perpendicular to an extension direction of the recessed portion 401. Based on this setting method, it can be ensured that the common layer 204 accommodated in the recessed portion 401 has a sufficient length to ensure that the the lateral leakage current path between two adjacent sub-pixels 2 is extended.

For example, in some embodiments of the present disclosure, the light-shielding material includes a photosensitive material. In some embodiments of the present disclosure, the photosensitive material is selected to form the light-shielding material, during the manufacturing of the light-shielding material, the light-shielding material layer with preset patterns can be manufactured by coting the light-shielding material layer, exposing the light-shielding material layer through the mask, and curing, thereby eliminating the need to form the photoresist layer on the surface of the light-shielding material layer, and eliminating the need to remove the photoresist layer, which is beneficial to simplifying the manufacturing process of the display panel.

In some embodiments of the present disclosure, one of the first pixel definition layer 21 and the second pixel definition layer 22 includes a positive photosensitive material, and the other one includes a negative photosensitive material. Based on this setting method, during the manufacturing of the first pixel definition layer 21 and the second pixel definition layer 22, the influence of the manufacturing process of one on the other one can be reduced, which is beneficial to improving the manufacturing yield of the display panel.

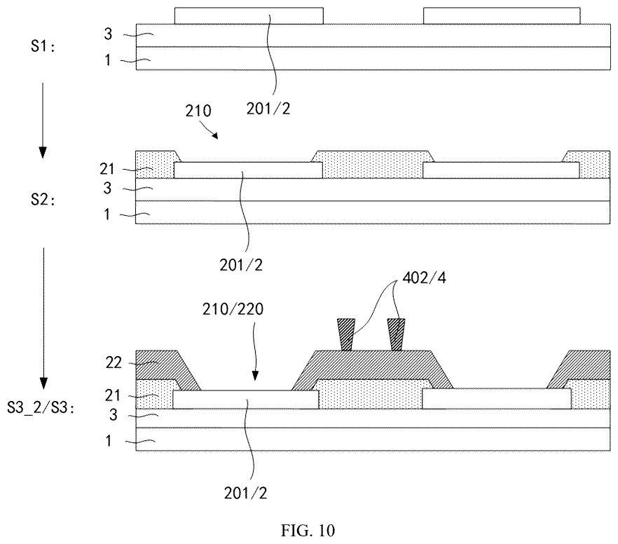

Based on the same inventive concept, an embodiment of the present disclosure further provides a method for manufacturing a display panel. As shown in FIG. 2, FIG. 9 and FIG. 10. Where FIG. 9 and FIG. 10 are schematic flowcharts of two methods for manufacturing a display panel according to some embodiments of the present disclosure, the method for manufacturing a display panel includes the following steps.

Step S1: a substrate 1 is provided. For example, as shown in FIG. 9 and FIG. 10, the manufacturing method further includes the steps of forming a driving function layer 3 on a side of the substrate 1, and forming a first electrode 201 of a light-emitting element on a side of the driving function layer 3 away from the substrate 1. The driving function layer 3 includes a pixel driving circuit for driving the light-emitting element to emit light.

Step S2: a first pixel definition layer 21 is formed on a side of the substrate 1. The first pixel definition layer 21 includes the first pixel opening 210; the first pixel opening 210 exposes at least part of the first electrode 201.

Step S3: the second pixel definition layer 22 is formed on a side of the first pixel definition layer 21 away from the substrate 1. In some embodiments of the present disclosure, at least one of the first pixel definition layer 21 and the second pixel definition layer 22 includes a light-shielding material, and the light-shielding material can reduce the reflectivity of the display panel. As shown in FIG. 9 and FIG. 10, the second pixel definition layer 22 includes a second pixel opening 220, the second pixel opening 220 at least partially overlaps the first pixel opening 210 along a direction perpendicular to a plane of the substrate 1, the second pixel opening 220 exposes at least part of the first electrode 201, the partition portion 4 is formed that at least partially surrounds the first pixel opening 210 and the second pixel opening 220, and the partition portion 4 can reduce the lateral leakage current of the display panel and improve the display effect of the display panel.

For example, as shown in FIG. 9, the step S3 includes step S3_1 of setting the partition portion 4 as the recessed portion 401, the recessed portion 401 is recessed from a surface of the second pixel definition layer 22 away from the first pixel definition layer 21 toward the side close to the first pixel definition layer 21. Additionally/alternatively, as shown in FIG. 10, the step S3 includes step S3_2 of setting the partition portion 4 as the first protrusion portion 402, the first protrusion portion 402 protrudes from a surface of the second pixel definition layer 22 away from the first pixel definition layer 21 toward the side away from the first pixel definition layer 21.

It can be understood that the method for manufacturing a display panel according to some embodiments of the present disclosure further includes steps of continuously forming the common layer and the second electrode after the partition portion 4 is formed to obtain the display panel as shown in FIG. 2 or FIG. 4.

In the method for manufacturing a display panel according to some embodiments of the present disclosure, by providing the first pixel definition layer 21 and the second pixel definition layer 22 in the display panel, and configuring at least one of the two to include the light-shielding material that can absorb external ambient light incident on the display panel and ambient light reflected by the metal structure inside the display panel, the reflectivity of the display panel can be reduced.

Furthermore, in the embodiments of the present disclosure, by providing the partition portion 4 in the display panel that can extend or block the lateral leakage current path between two adjacent sub-pixels 2, the light leakage issue can be effectively solved, and the display effect of the display panel can be improved.

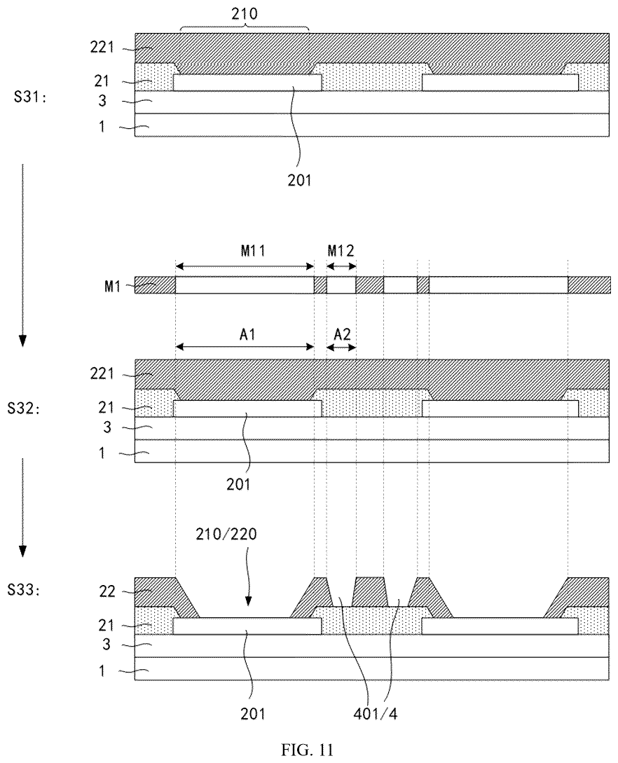

As shown in FIG. 9, when the partition portion 4 is configured to include the recessed portion 401, the recessed portion 401 can be recessed from the surface of the second pixel definition layer 22 toward the side close to the substrate 1. In some embodiments of the present disclosure, as shown in FIG. 11, which is schematic diagram of a method for manufacturing a second pixel definition layer according to some embodiments of the present disclosure. The method for forming the second pixel definition layer includes the following steps.

Step S31: a first initial film layer 221 is formed on a side of the first pixel definition layer 21 away from the substrate 1, and the first initial film layer 221 includes the photosensitive material. As shown in FIG. 11, the first initial film layer 221 can cover the first pixel opening 210.

Step S32: a first mask M1 is provided, and the first initial film layer 221 is exposed through the first mask M1. As shown in FIG. 11, the first mask M1 includes a first transmission area M11 and a second transmission area M12. When aligning the first mask M1 with the first initial film layer 221, the first transmission area M11 is aligned with the first area A1, where the first area A1 is a preset area of the second pixel opening 220; and the second transmission area M12 is aligned with the second area A2, where the second area A2 is a preset area of the recessed portion 401. The first area A1 at least partially overlaps the orthographic projection of the first pixel opening 210 on the plane perpendicular to the substrate 1, and the second area A2 at least partially surrounds the first area A1.

Step S33: A portion of the first initial film layer 221 located in the first area A1 and the second area A2 is removed to obtain the second pixel definition layer 22 with the second pixel opening 220 in the first area A1 and the recessed portion 401 in the second area A2. The second pixel opening 220 and the recessed portion 401 both penetrate through the second pixel definition layer 22 along the direction perpendicular to the plane of the substrate 1.

By adopting this setting method, the recessed portion 401 and the second pixel opening 220 can be formed in the same manufacturing process, which is beneficial to reducing the manufacturing process of the display panel and simplifying the process. Moreover, in the embodiments of the present disclosure, by configuring the first initial film layer 221 to include the photosensitive material, the first initial film layer 221 can be directly exposed during the manufacturing of the second pixel opening 220 and the recessed portion 401, without the need for an additional step of coating the photoresist on the surface of the first initial film layer 221, which is beneficial to further simplifying the manufacturing process of the display panel. In addition, based on this setting method, it is helpful to set the angle between the side wall of the recessed portion 401 and the substrate 1 as large as possible, that is, the side wall of the recessed portion 401 can be more inclined, which is beneficial to extending the length of the common layer subsequently covered on the surface of the recessed portion 401, and thus beneficial to suppressing the lateral leakage current.

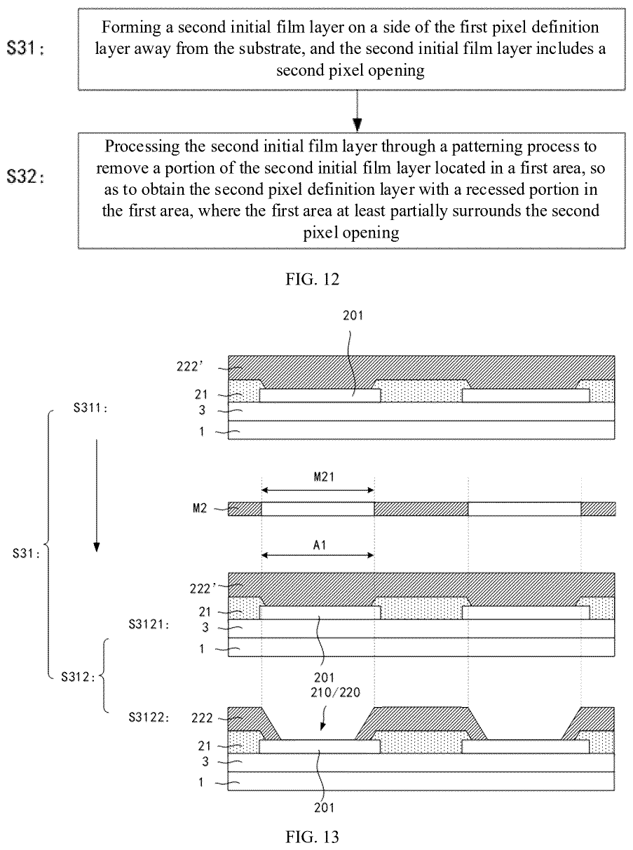

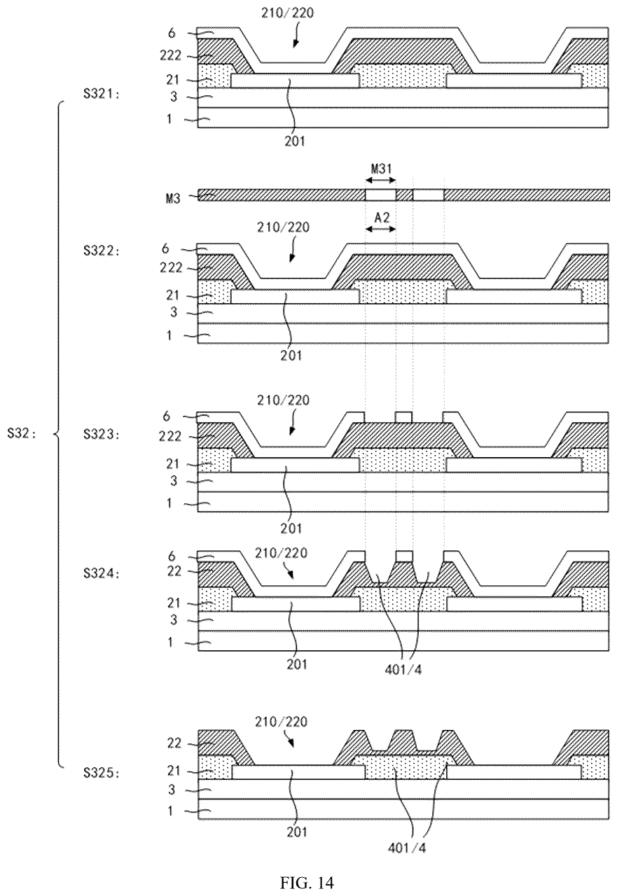

For example, as shown in FIG. 12, FIG. 13 and FIG. 14, where FIG. 12, FIG. 13 and FIG. 14 are schematic flowcharts of another three methods for manufacturing a display panel according to some embodiments of the present disclosure, respectively, when manufacturing the recessed portion 401 with the structure shown in FIG. 7, the method for forming the recessed portion 401 includes the following steps.

Step S31: a second initial film layer 222 is formed on a side of the first pixel definition layer 21 away from the substrate 1, the second initial film layer 222 includes the second pixel opening 220.

Step S32: the second initial film layer 222 is processed through the patterning process to remove the portion of the second initial film layer 222 located in the first area A1, so as to obtain the second pixel definition layer 22 with the recessed portion 401 in the first area A1. The first area A1 at least partially surrounds the second pixel opening 220, the depth of the recessed portion 401 is less than the thickness of the second pixel definition layer 22 along the direction perpendicular to the plane of the substrate 1, and the patterning process includes photoresist coating, exposing, developing and etching.

For example, as shown in FIG. 13, the step S31 includes the following steps.

Step S311: an initial film layer 222′ is formed on a side of the first pixel definition layer 21 away from the substrate 1.

Step S312: the initial film layer 222′ is patterned to form the second pixel opening 220 in the initial film layer 222′. For example, the initial film layer 222′ includes the photosensitive material.

In some embodiments of the present disclosure, as shown in FIG. 13, the patterning process includes the following steps.

Step S3121: a second mask M2 is provided, and the initial film layer 222′ is exposed through the second mask M2. As shown in FIG. 13, the second mask M2 includes a first transmission area M21, and when the second mask M2 is aligned with the initial film layer 222′, the first transmission area M21 is aligned with the first area A1, where the first area A1 is a preset area of the second pixel opening 220, and the first area A1 at least partially overlaps the orthographic projection of the first pixel opening 210 on the plane perpendicular to the substrate 1.

Step S3122: the portion of the initial film layer 222′ located in the first area A1 is removed to obtain the second pixel definition layer 22 with the second pixel opening 220 in the first area A1. The second pixel opening 220 penetrates through the second pixel definition layer 22 along the direction perpendicular to the plane of the substrate 1. The second pixel definition layer 22 having the second pixel opening 220 is the second initial film layer 222.

For example, as shown in FIG. 14, the method for processing the second initial film layer 222 through the patterning process includes the following steps.

Step S321: a photoresist layer 6 is coated on a side of the second initial film layer 222 away from the substrate 1, and the photoresist layer 6 includes a positive photoresist or a negative photoresist. The following description is made by taking the positive photoresist as an example.

Step S322: a third mask M3 is provided, and the photoresist layer 6 is exposed through the third mask M3. The third mask M3 includes a transmission area M31, and when the third mask M3 is aligned with the second initial film layer 222, the transmission area M31 is aligned with the second area A2, where the second area A2 is a preset area of the recessed portion 401.

Step S323: the portion of the photoresist layer 6 corresponding to the transmission area M31 is removed.

Step S324: the portion of the second initial film layer 222 that is not covered by the photoresist layer 6 is etched to obtain the second pixel definition layer 22 having the recessed portion 401. As shown in FIG. 14, the depth of the recessed portion 401 is less than the depth of the second pixel definition layer 22, that is, the recessed portion 401 does not penetrate through the second pixel definition layer 22.

Step S325: the photoresist layer 6 is stripped.

By adopting this setting method, in the step S324, it is possible to avoid the contact between the etchant forming the recessed portion 401 and the first pixel definition layer 21, and to prevent the first pixel definition layer 21 from being affected by the etchant, which is beneficial to protecting the reliability of the first pixel definition layer 21. For example, when the first pixel definition layer 21 includes the light-shielding material, it is possible to avoid the problem that the first pixel definition layer 21 is affected by the etchant and fades, thereby affecting the light-shielding performance and thus causing an increase in the reflectivity of the display panel.

For example, as shown in FIG. 7 and FIG. 8, the method for manufacturing a display panel further includes: forming a supporting portion 5 on a side of the first pixel definition layer 21 away from the substrate 1. The supporting portion 5 can improve the compressive strength of the display panel 100, and is configured to support the mask used in the manufacturing process to prevent the mask from scratching other previously manufactured film layers.

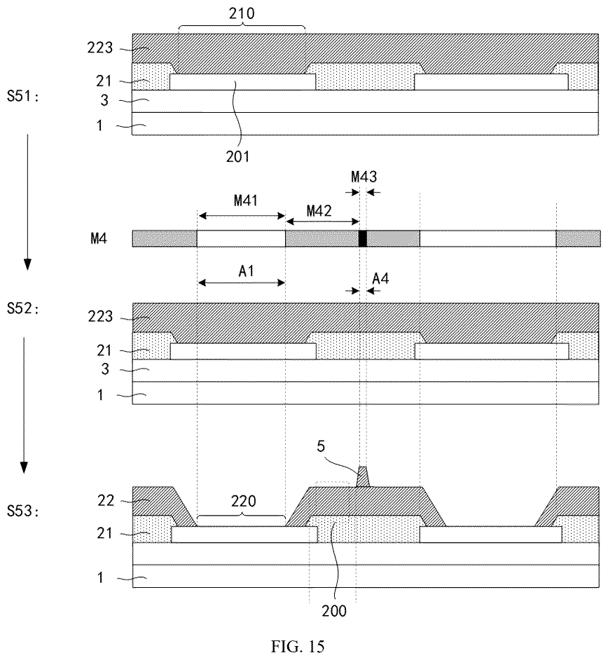

For example, as shown in FIG. 15, which is a schematic diagram of another method for manufacturing a display panel according to some embodiments of the present disclosure, the method for forming the supporting portion 5 as shown in FIG. 7 includes the following steps.

Step S51: a third initial film layer 223 is formed on a side of the first pixel definition layer 21 away from the substrate 1. The first pixel definition layer 21 includes the first pixel opening 210, the third initial film layer 223 can fill the first pixel opening 210, and the third initial film layer 223 includes the photosensitive material.

Step S52: a half-tone mask M4 is provided, and the third initial film layer 223 is patterned through the half-tone mask M4. As shown in FIG. 15, the half-tone mask M4 includes a first transmission area M41, a second transmission area M42 and a light-shielding area M43, and the light transmittance of the first transmission area M41 is greater than the light transmittance of the second transmission area M42. In some embodiments of the present disclosure, when the half-tone mask M4 is aligned with the third initial film layer 223, the first transmission area M41 is aligned with the first area A1, where the first area A1 is a preset area of the second pixel opening 220; the second transmission area M42 is aligned with the third area A3, where the third area A3 is an area in the display panel where the second pixel opening, the supporting portion and the recessed portion are not formed; and the light-shielding area M43 is aligned with the fourth area A4, where the fourth area A4 is a preset area of the supporting portion 5. The first area A1 at least partially overlaps the orthographic projection of the first pixel opening 210 on the plane perpendicular to the substrate 1.

Step S53: the portion of the third initial film layer 223 corresponding to the first transmission area M41 is completely removed to form the second pixel opening 220, the portion of the third initial film layer 223 corresponding to the second transmission area M42 is partially removed to form the spacing portion 200 in the second pixel definition layer 22 that avoids the second pixel opening 220 and the supporting portion 5, and the portion of the third initial film layer 223 corresponding to the light-shielding area M13 is retained to form the supporting portion 5. As shown in FIG. 15, the distance between the surface of the spacing portion 200 away from the substrate 1 and the substrate 1 is smaller than the distance between the surface of the supporting portion 5 away from the substrate 1 and the substrate 1.

By adopting this setting method, the second pixel definition layer 22 and the supporting portion 5 can be formed simultaneously using a single process, which is beneficial to reducing the process complexity of the display panel and improving the process efficiency.

For example, after the step S53, the method for manufacturing a display panel according to some embodiments of the present disclosure further includes a process of providing the third mask to etch the second pixel definition layer 22, so as to form the recessed portion 401. This process can be performed with reference to step S321 to step S325 shown in FIG. 14, which will not be elaborated in the present disclosure.

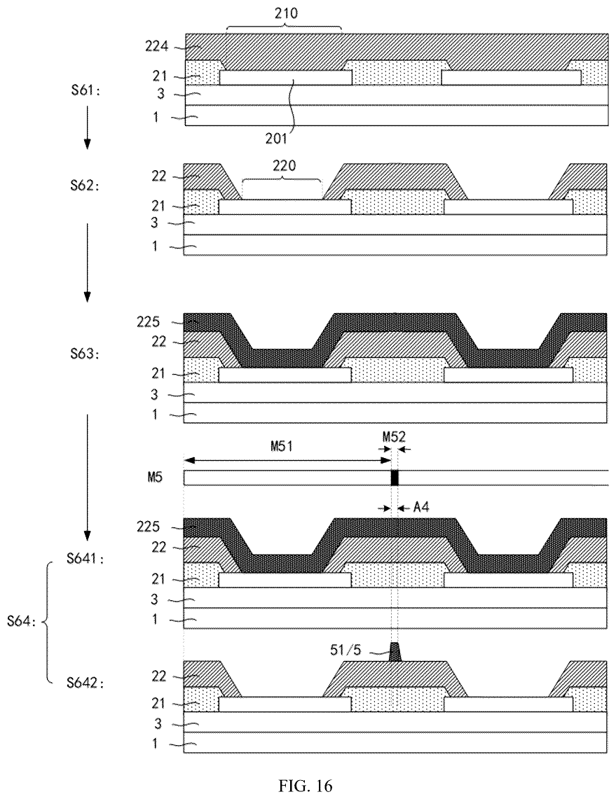

For example, as shown in FIG. 16, which is a schematic diagram of a method for manufacturing a display panel according to some embodiments of the present disclosure, another method for forming the supporting portion 5 as shown in FIG. 7 includes the following steps.

Step S61: a fourth initial film layer 224 is formed on a side of the first pixel definition layer 21 away from the substrate 1, and the fourth initial film layer 224 can cover the first pixel opening 210 in the first pixel definition layer 21.

Step S62: the fourth initial film layer 224 is patterned to form the second pixel definition layer 22 with the second pixel opening 220.

Step S63: a fifth initial film layer 225 is formed on a side of the second pixel definition layer 22 away from the substrate 1.

Step S64: the fifth initial film layer 225 is patterned to form the supporting portion 5.

For example, the fifth initial film layer 225 includes the photosensitive material, and accordingly, the patterning process includes exposing and curing. As shown in FIG. 16, the exposure process includes the following steps.

Step S641: a fifth mask M5 as shown in FIG. 16 is provided, where the fifth mask M5 includes a first transmission area M51 and a light-shielding area M52, the fifth initial film layer 225 is exposed through the fifth mask M5. In some embodiments of the present disclosure, when the fifth mask M5 is aligned with the fifth initial film layer 225 and the fifth initial film layer 225 includes the positive photosensitive material, the light-shielding area M52 is aligned with the fourth area A4, where the fourth area A4 is a preset area of the supporting portion 5.

Step S642: the portion of the fifth initial film layer 225 that does not correspond to the light-shielding area M52 is removed, and the portion of the fifth initial film layer 225 that is not removed and corresponds to the light-shielding area M52 forms the supporting portion 5.

Alternatively, the fifth initial film layer 225 may not include the photosensitive material, in which case the patterning process includes the steps of coating the photoresist on the side of the fifth initial film layer 225 away from the substrate 1, exposing, developing, etching, and removing the photoresist.

For example, the fourth initial film layer 224 may include the photosensitive material, and accordingly, the patterning process in the step S62 includes exposing and curing. The exposure process refers to providing the second mask M2 as shown in FIG. 13, and exposing the fourth initial film layer 224 through the second mask M2. Alternatively, the fourth initial film layer 224 may not include the photosensitive material, and the patterning process includes the steps of coating the photoresist on the side of the fourth initial film layer 224 away from the substrate, exposing, developing, etching, and removing the photoresist.

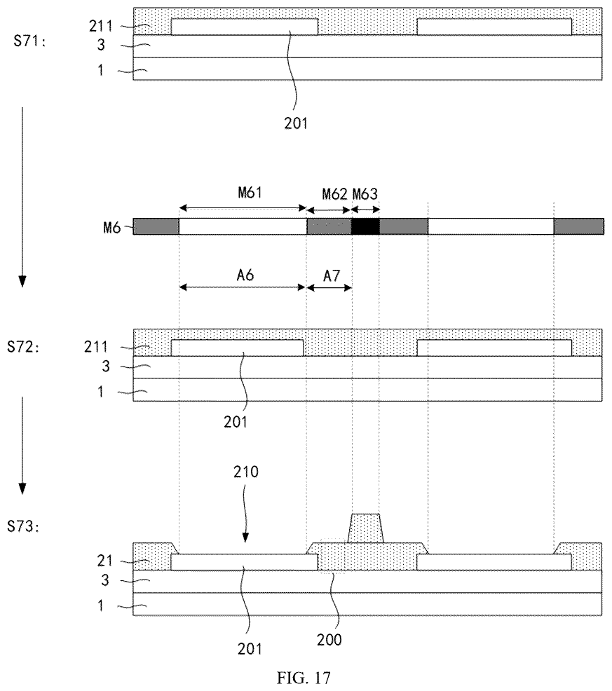

In some embodiments of the present disclosure, the method for forming the supporting portion 5 having the configuration as shown in FIG. 8 includes: forming the supporting portion 5 between the first pixel definition layer 21 and the second pixel definition layer 22. For example, as shown in FIG. 17, which is a schematic flowchart of another method for manufacturing a display panel according to some embodiments of the present disclosure, the manufacturing method includes the following steps.

Step S71: an initial film layer 211 is formed on a side of the first electrode 201 away from the substrate 1. For example, the initial film layer 211 includes the photosensitive material.

Step S72: a half-tone mask M6 is provided, and the initial film layer 211 is patterned through the half-tone mask M6. As shown in FIG. 17, the half-tone mask M6 includes a first transmission area M61, a second transmission area M62 and a light-shielding area M63, and the light transmittance of the first transmission area M61 is greater than the light transmittance of the second transmission area M62. For example, as shown in FIG. 17, when the half-tone mask M6 is aligned with the initial film layer 211, the first transmission area M61 is aligned with the sixth area A6, where the sixth area A6 a preset area of the first pixel opening 210 in the display panel; the second transmission area M62 is aligned with the seventh area A7, where the seventh area A7 is an area in the display panel where the first pixel opening 210 and the supporting portion 5 are not formed; and the light-shielding area M13 is aligned with the fourth area A4, and the fourth area A4 is a preset area of the supporting portion 5. The sixth area A6 at least partially overlaps the orthographic projection of the first electrode 201 on the plane perpendicular to the substrate 1.

Step S73: the portion of the initial film layer 211 corresponding to the first transmission area M61 is completely removed to form the first pixel opening 210, the portion of the initial film layer 211 corresponding to the second transmission area M62 is partially removed to form the spacing portion 200 in the first pixel definition layer 21 that avoids the first pixel opening 210 and the supporting portion 5, and the portion of the initial film layer 211 corresponding to the light-shielding area M63 is retained to form the supporting portion 5.

By adopting this setting method, the first pixel definition layer 21 and the supporting portion 5 can be formed simultaneously using a single process, which is beneficial to reducing the process complexity of the display panel and improving the process efficiency.

Alternatively, in some embodiments of the present disclosure, the first pixel opening 210 and the supporting portion 5 can also be formed in different steps to better modify the morphologies of the first pixel opening 210 and the supporting portion 5.

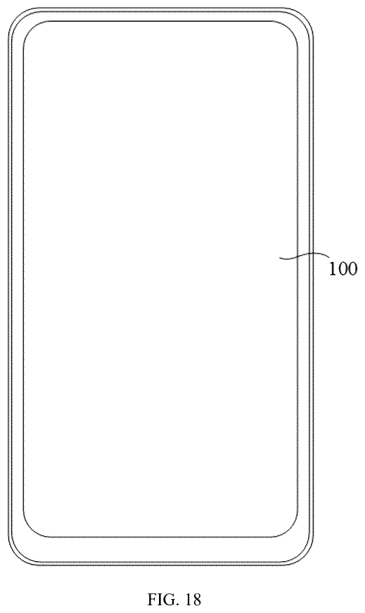

Based on the same inventive concept, an embodiment of the present disclosure further provide a display apparatus. As shown in FIG. 18, which is a schematic diagram of a display apparatus according to some embodiments of the present disclosure, the display apparatus includes the display panel 100 described above. The specific structure of the display panel 100 has been described in detail in the above embodiments, which will not be elaborated herein. The display apparatus shown in FIG. 18 is only for schematic illustration. The display apparatus can be any apparatus with a display function, such as a mobile phone, a tablet, a laptop, an e-book, a television and a smartwatch, which is not limited thereto in the present disclosure.

The above description is merely preferred embodiments of the present disclosure, and is not intended to limit the present disclosure. Any modification, equivalent substitution, improvement, etc. made within the spirit and principle of the present disclosure shall fall within the protection scope of the present disclosure.

It should be noted that the above embodiments are merely used to illustrate the technical solutions of the present disclosure, rather than to limit it. Although the present disclosure has been described in detail with reference to the above embodiments, those skilled in the art should understand that they can still modify the technical solutions described in the above embodiments, or replace some or all of the technical features therein by equivalents. However, these modifications or replacements do not make the essence of the corresponding technical solutions deviate from the scope of the technical solutions of the embodiments of the present disclosure.

What is claimed is:

1. A display panel, comprising:
a substrate;
a first pixel definition layer located on a side of the substrate, wherein the first pixel definition layer comprises a first pixel opening;
a second pixel definition layer located on a side of the first pixel definition layer away from the substrate, wherein at least one of the first pixel definition layer and the second pixel definition layer comprises a light-shielding material, the second pixel definition layer comprises a second pixel opening, and the second pixel opening at least partially overlaps the first pixel opening along a direction perpendicular to a plane of the substrate;
a light-emitting layer at least partially located in the first pixel opening and the second pixel opening; and
a partition portion at least partially surrounding the first pixel opening and the second pixel opening, wherein the partition portion comprises a recessed portion or a first protrusion portion, the recessed portion is recessed from a surface of the second pixel definition layer away from the first pixel definition layer toward a direction close to the first pixel definition layer, and the first protrusion portion protrudes from the surface of the second pixel definition layer away from the first pixel definition layer toward a direction away from the first pixel definition layer.

2. The display panel according to claim 1, wherein the partition portion comprises the recessed portion, and the recessed portion penetrates through the second pixel definition layer along the direction perpendicular to the plane of the substrate.

3. The display panel according to claim 1, wherein the partition portion comprises the recessed portion, and a depth of the recessed portion is less than a thickness of the second pixel definition layer along the direction perpendicular to the plane of the substrate.

4. The display panel according to claim 1, further comprising:
a supporting portion;
wherein the second pixel definition layer comprises a spacing portion, and the spacing portion and the supporting portion are arranged in a staggered manner along the direction perpendicular to the plane of the substrate, and a distance between a surface of the supporting portion away from the substrate and the substrate is greater than a distance between a surface of the spacing portion away from the substrate and the substrate.

5. The display panel according to claim 4, further comprising:
a second protrusion portion, wherein the second protrusion portion protrudes from the surface of the second pixel definition layer away from the first pixel definition layer to the direction away from the first pixel definition layer; and
wherein the supporting portion comprises the second protrusion portion.

6. The display panel according to claim 5, wherein the supporting portion and the second pixel definition layer are formed in a same process.

7. The display panel according to claim 4, further comprising:
a third protrusion portion, wherein the third protrusion portion protrudes from a surface of the first pixel definition layer away from the substrate to a direction away from the substrate; and
wherein the supporting portion comprises the third protrusion portion.

8. The display panel according to claim 7, wherein the supporting portion and the first pixel definition layer are formed in a same process.

9. The display panel according to claim 4, wherein a height b of the supporting portion satisfies: b≥1 μm.

10. The display panel according to claim 1, wherein the partition portion comprises the recessed portion, and a depth a of the recessed portion satisfies: a≥0.6 μm.

11. The display panel according to claim 1, wherein a minimum distance c between an edge of the first pixel opening and an edge of the second pixel opening satisfies: c≥1.5 μm.

12. The display panel according to claim 1, wherein a thickness d of the first pixel definition layer satisfies: d≥1 μm.

13. The display panel according to claim 1, wherein the partition portion comprises the recessed portion, a width e of the recessed portion satisfies: e≥2 μm, and a width direction of the recessed portion is perpendicular to an extension direction of the recessed portion.

14. The display panel according to claim 1, wherein the light-shielding material comprises a photosensitive material.

15. The display panel according to claim 1, wherein one of the first pixel definition layer and the second pixel definition layer comprises a positive photosensitive material, and the other one of the first pixel definition layer and the second pixel definition layer comprises a negative photosensitive material.

16. A method for manufacturing a display panel, comprising:
providing a substrate;
forming a first pixel definition layer on a side of the substrate, wherein the first pixel definition layer comprises a first pixel opening;
forming a second pixel definition layer on a side of the first pixel definition layer away from the substrate, wherein at least one of the first pixel definition layer and the second pixel definition layer comprises a light-shielding material, the second pixel definition layer comprises a second pixel opening, and the second pixel opening at least partially overlaps the first pixel opening along a direction perpendicular to a plane of the substrate; and
forming a partition portion at least partially surrounding the first pixel opening and the second pixel opening, wherein the partition portion comprises a recessed portion or a first protrusion portion, the recessed portion is recessed from a surface of the second pixel definition layer away from the first pixel definition layer toward a direction close to the first pixel definition layer, the first protrusion portion protrudes from the surface of the second pixel definition layer away from the first pixel definition layer toward a direction away from the first pixel definition layer.

17. The method for manufacturing a display panel according to claim 16, wherein the partition portion comprises the recessed portion; and
wherein the forming the second pixel definition layer comprises:
forming a first initial film layer on the side of the first pixel definition layer away from the substrate, wherein the first initial film layer comprises a photosensitive material;
exposing the first initial film layer; and
removing a portion of the first initial film layer located in a first area and a second area, to obtain the second pixel definition layer with the second pixel opening in the first area and the recessed portion in the second area, wherein the first area is a preset area of the second pixel opening, the second area at least partially surrounds the second pixel opening, and the recessed portion penetrates through the second pixel definition layer along the direction perpendicular to the plane of the substrate.

18. The method for manufacturing a display panel according to claim 16, wherein the partition portion comprises the recessed portion; and
wherein forming the recessed portion comprises:
forming a second initial film layer on the side of the first pixel definition layer away from the substrate; and
processing the second initial film layer through a patterning process to remove a portion of the second initial film layer located in a first area, so as to obtain the second pixel definition layer with the recessed portion in the first area, wherein the first area at least partially surrounds the second pixel opening, a depth of the recessed portion is less than a thickness of the second pixel definition layer along the direction perpendicular to the plane of the substrate, and the patterning process comprises photoresist coating, exposing, etching and developing.

19. The method for manufacturing a display panel according to claim 16, further comprising:
forming a supporting portion on the side of the first pixel definition layer away from the substrate,
wherein the forming the supporting portion comprises:
forming a third initial film layer on the side of the first pixel definition layer away from the substrate;
providing a half-tone mask to pattern the third initial film layer, wherein the half-tone mask comprises a first transmission area, a second transmission area and a light-shielding area, and a light transmittance of the first transmission area is greater than a light transmittance of the second transmission area; and
completely removing a portion of the third initial film layer corresponding to the first transmission area to form the second pixel opening, partially removing a portion of the third initial film layer corresponding to the second transmission area to form the second pixel definition layer, and retaining a portion of the third initial film layer corresponding to the light-shielding area to form the supporting portion.

20. A display apparatus, comprising a display panel;
wherein the display panel comprises:
a substrate;
a first pixel definition layer located on a side of the substrate, wherein the first pixel definition layer comprises a first pixel opening;
a second pixel definition layer located on a side of the first pixel definition layer away from the substrate, wherein at least one of the first pixel definition layer and the second pixel definition layer comprises a light-shielding material, the second pixel definition layer comprises a second pixel opening, and the second pixel opening at least partially overlaps the first pixel opening along a direction perpendicular to a plane of the substrate;
a light-emitting layer at least partially located in the first pixel opening and the second pixel opening; and
a partition portion at least partially surrounding the first pixel opening and the second pixel opening, wherein the partition portion comprises a recessed portion or a first protrusion portion, the recessed portion is recessed from a surface of the second pixel definition layer away from the first pixel definition layer toward a direction close to the first pixel definition layer, and the first protrusion portion protrudes from the surface of the second pixel definition layer away from the first pixel definition layer toward a direction away from the first pixel definition layer.
